(19) United States
(12) Patent Application Publication
(10) Pub. No.: US 2015/0013593 A1
(43) Pub. Date: Jan. 15, 2015

(54) THIN FILM FORMATION

(71) Applicant: Universiteit Leiden, Leiden (NL)

(72) Inventor: Guocai Dong, Leiden (NL)

(73) Assignee: Universiteit Leiden, Leiden (NL)

(21) Appl. No.: 14/377,173

(22) PCT Filed: Feb. 4, 2013
(86) PCT No.: PCT/EP2013/052152

§ 371 Date: Aug. 6, 2014

Related U.S. Application Data
(60) Provisional application No. 61/595,873, filed on Feb. 7, 2012.

(30) Foreign Application Priority Data
Feb. 7, 2012 (GB) 1202080.6

(51) Int. Cl. C30B 25/16; C30B 29/02; H01L 21/02

(52) U.S. Cl. CPC C30B 25/16; H01L 21/02527; H01L 21/0262; H01L 21/02425; C30B 29/02
USPC 117/88

(57) ABSTRACT

A method of forming a graphene film on a surface (20) of a substrate comprises the steps of: (i) locating a carbon source (22) at, or in a vicinity of the surface (20) of the substrate; (ii) controlling ambient conditions at the surface (20) of the substrate to inhibit graphene nucleation on the surface (20); (iii) applying a temporary change of one or more of the ambient conditions at a localised site (30) on the surface (20) of the substrate to initiate graphene nucleation at the localised site (30); (iv) controlling the ambient conditions at the surface (20) of the substrate, following initiation of graphene nucleation at the localised site, to simultaneously inhibit graphene nucleation and enable graphene growth on the surface (20).

This invention relates to a method of forming a graphene film on a surface of a substrate.

Graphene has specific properties that render it compatible with a wide range of applications such as fast and flexible electronics, lasers, bio-sensors, atomically thin protective coatings, hydrogen storage and energy storage. In particular, graphene demonstrates higher carrier mobility than conventional semiconductor materials, which can be exploited to improve the speed of electronics including microprocessors.

Synthesis of large films of graphene is highly sought after to increase the range of practical applications that involve the use of graphene. However, the electronic quality of a graphene film is often limited by the presence of crystallographic defects in the graphene film. Such defects may arise when multiple graphene domains with different orientations are assembled to define a multi-domain graphene film with domain boundaries. This in turn adversely affects the uniformity of properties, and performance, of the graphene film.

According to an aspect of the invention, there is provided a method of forming a graphene film on a surface of a substrate comprising the steps of:
(I) locating a carbon source at, or in a vicinity of, the surface of the substrate;
(ii) controlling ambient conditions at the surface of the substrate to inhibit graphene nucleation on the surface;
(iii) applying a temporary change to one or more of the ambient conditions at a localised site on the surface of the substrate to initiate graphene nucleation at the localised site;
(iv) controlling the ambient conditions at the surface of the substrate, following initiation of graphene nucleation at the localised site, to simultaneously inhibit graphene nucleation and enable graphene growth on the surface.

Synthesis of graphene involves nucleation and growth of graphene. Graphene nucleation relates to formation of a new graphene nucleus at a site without an existing graphene nucleus, while graphene growth relates to an increase in size of an existing graphene nucleus.

The inventors have discovered that synthesis of large films of high quality graphene on the surface of the substrate is possible through control of ambient conditions at the surface.

Initially a carbon source is located at, or in the vicinity of, the surface of the substrate. For example, the carbon source may be located above, on or near the surface, or inside the substrate underneath the surface.

The carbon source may be any type of source of carbon that is capable of supplying carbon atoms. For example, the carbon source may include one or more of: a carbon-containing gas, a carbon-containing liquid, carbon contamination of the substrate, carbon atoms on the surface, carbon-containing molecules on the surface, carbon atoms dissolved in the substrate, carbon-containing molecules dissolved in the substrate, an atomic carbon source and carbon ions.

Ambient conditions at the surface are controlled to inhibit graphene nucleation, which requires formation of a graphene nucleus that exceeds a critical nucleus size. The critical nucleus size for graphene nucleation is the minimum physical dimensions of a graphene cluster required to achieve stability thereof and thereby obtain a stable graphene nucleus. A graphene cluster that is smaller than the critical nucleus size for graphene nucleation is in an unstable state, which causes the graphene cluster to de-cluster into individual carbon atoms.

Graphene nucleation may be inhibited, for example, by controlling the ambient conditions at the surface to control the carbon adatom density on the surface to be lower than the required density of carbon adatoms on the surface for graphene nucleation to take place at an observable rate. This results in a set of ambient conditions in which graphene nucleation on the surface is negligible, if not nil.

Application of a temporary change of one or more of the ambient conditions at the localised site is then carried out to form a stable graphene nucleus at the localised site, for example, by increasing the carbon adatom density at the localised site to be sufficiently high. Meanwhile the ambient conditions elsewhere on the surface and away from the localised site remain unchanged and thereby prevent graphene nucleation from taking place elsewhere on the surface, away from the localised site.

The temporary nature of the change of one or more of the ambient conditions at the localised site subsequently results in lapsing of the temporary change of one or more of the ambient conditions at the localised site, which inhibits further graphene nucleation at the localised site.

After the temporary change of one or more of the ambient conditions at the localised site has lapsed, the ambient conditions at the surface are controlled to simultaneously inhibit graphene nucleation and enable graphene growth on the surface. This may be achieved by, for example, controlling the ambient conditions at the surface to control the carbon adatom density on the surface to be lower than the required density of carbon adatoms on the surface for graphene nucleation to take place at an observable rate, and higher than the required density of carbon adatoms on the surface of the substrate for graphene growth to take place at an observable rate. This results in a set of ambient conditions in which graphene growth from existing graphene nuclei can occur on the surface, but graphene nucleation on the surface is negligible, if not nil. Consequently this enables subsequent graphene growth from the newly formed graphene nucleus at the localised site, which eventually leads to formation of a graphene film on the surface of the substrate.

Control of graphene nucleation on the surface of the substrate in this manner may be used to restrict the number of graphene nuclei on the surface of the substrate and/or control the placement of graphene nuclei on the surface of the substrate so as to create relatively large distances between neighbouring graphene nuclei. These restrictions in the number and placement of graphene nuclei may be used to limit the number of graphene domains formed on the surface. This in turn reduces the number of domain boundaries, and therefore the overall number of defects, in the resultant graphene film.

Otherwise omission of the step of controlling ambient conditions at the surface of the substrate to inhibit graphene nucleation on the surface may result in the formation of multiple graphene nuclei that is located at different sites across the surface. The presence of multiple graphene nuclei that is available for subsequent graphene growth may result in formation of multiple graphene domains with different orientations, which assemble to define a multi-domain graphene film. In addition, uncontrolled placement of graphene nuclei may result in formation of graphene domains in close proximity to each other, which would limit the size of the graphene domains and thereby increase the number of defects in the resultant graphene film.

Preferably the step of controlling ambient conditions at the surface of the substrate to inhibit graphene nucleation on the surface further involves simultaneously controlling the ambient conditions at the surface of the substrate to enable graphene growth on the surface.

Control of the ambient conditions in this manner enables near-instantaneous graphene growth as soon as a stable graphene nucleus is formed at the localised site.

In embodiments of the invention, the ambient conditions may be selected from a group to including temperature, gas pressure, rate of decomposition of absorbed carbon-containing molecules, carbon adatom density on the surface of the substrate, carbon concentration of the substrate, electrical potential, substrate cooling rate and surface chemistry.

As outlined earlier, graphene nucleation and graphene growth are functions of the ambient conditions at the surface, one or more of which may be fixed to simplify the control of graphene nucleation and graphene growth on the surface.

The step of controlling ambient conditions at the surface of the substrate may involve controlling the temperature at the surface to be in the range of 500 K to 2000 K. This may be followed by the step of applying a temporary change to one or more of the ambient conditions at a localised site on the surface of the substrate involves temporarily changing the temperature at the localised site to be in the range of 1 K to 2000 K.

The step of controlling ambient conditions at the surface of the substrate may involve controlling the gas pressure at the surface to be in the range of 1×10⁻⁹ mbar to 3 bar. This may be followed by the step of applying a temporary change to one or more of the ambient conditions at a localised site on the surface of the substrate involves temporarily changing the gas pressure at the localised site to be in the range of 1×10⁻⁸ mbar to 10 bar.

The step of controlling ambient conditions at the surface of the substrate may involve controlling the rate of decomposition of absorbed carbon-containing molecules at the surface to be in the range of 0.0001% to 10%. This may be followed by the step of applying a temporary change to one or more of the ambient conditions at a localised site on the surface of the substrate involves temporarily changing the rate of decomposition of absorbed carbon-containing molecules at the localised site to be in the range of 0.01% to 100%.

The step of controlling ambient conditions at the surface of the substrate may involve controlling the carbon concentration of the substrate at the surface to be in the range of 0.0001% to 10%. This may be followed by the step of applying a temporary change to one or more of the ambient conditions at a localised site on the surface of the substrate that involves temporarily changing the carbon concentration of the substrate at the localised site to be in the range of 0.01% to 100%.

The step of controlling ambient conditions at the surface of the substrate may involve controlling the electrical potential at the surface to be in the range of 0 to 1 kV. This may be followed by the step of applying a temporary change to one or more of the ambient conditions at a localised site on the surface of the substrate that involves temporarily changing the electrical potential at the localised site to be in the range of 0.1 V to 10 kV.

The step of controlling ambient conditions at the surface of the substrate may involve controlling the substrate cooling rate at the surface to be in the range of 0.01 K/sec to 1000 K/sec. This may be followed by the step of applying a temporary change of one or more of the ambient conditions at a localised site on the surface of the substrate involves temporarily changing the substrate cooling rate at the localised site to be in the range of 0.1 K/sec to 1500 K/sec.

Variation in surface chemistries between carbon adatoms and surfaces of different materials means that the critical nucleus size for graphene nucleation is influenced by the material of substrate used. Thus, graphene nucleation may be inhibited by using a substrate made from a material that corresponds to a specific critical nucleus size for graphene nucleation and controlling the ambient conditions on the surface of the substrate to hinder formation of a graphene cluster that exceeds the specific critical nucleus size. A catalyst may then be deposited at the localised site to alter the local surface chemistry and thereby locally initiate graphene nucleation, whereby the catalyst is made from a different material that corresponds to a smaller critical nucleus size for graphene nucleation. This in turn causes graphene nucleation to occur on the deposited catalyst and thereby results in formation of a graphene nucleus, which acts as a seed for subsequent graphene growth.

The critical nucleus size for graphene nucleation is also influenced by temperature of the substrate, which may be controlled to selectively initiate graphene nucleation at the localised site on the surface of the substrate in accordance with the method of the invention.

Preferably the step of applying a temporary change of one or more of the ambient conditions at a localised site on the surface of the substrate involves formation of a single graphene nucleus on the surface.

Control of graphene nucleation at the localised site to form a single graphene nucleus on the surface permits growth of a single graphene domain with a single orientation so as to form a single-domain graphene film without any domain boundaries on the surface.

Initiation of temporary graphene nucleation at the localised site may however result in the formation of multiple graphene nuclei and therefore the subsequent growth of multiple graphene domains, all of which emanates from the localised site. However, one of these graphene domains will be energetically more favourable. Graphene growth from the energetically more favourable domain will therefore be faster than graphene growth from the other graphene domains. This in turn means that after a short period of graphene growth, the graphene domains will assemble to define a single domain, leading to a single-domain character for the rest of the resultant graphene film on the surface of the substrate.

After the temporary change of one or more of the ambient conditions at the localised site has been applied, it may automatically lapse on its own. However, action is required to prompt a lapse in the temporary change of one or more of the ambient conditions at the localised site in circumstances whereby the lapse does not automatically take place.

Thus, in embodiments of the invention, the method may further include the step of removing the temporary change of one or more of the ambient conditions at the localised site subsequent to the step of applying a temporary change of one or more of the ambient conditions at a localised site on the surface of the substrate.

There are various ways of applying a temporary change of one or more of the ambient conditions at the localised site to trigger graphene nucleation at the localised site. For example, the step of applying a temporary change of one or more of the ambient conditions at a localised site on the surface of the substrate may involve:
impingement of a focused laser beam, focused ion beam or electron beam at the localised site;
depositing a catalyst at the localised site to increase a rate of decomposition of absorbed carbon-containing molecules at the localised site;
positioning of a tip near the localised site and applying a voltage difference between the localised site and the tip;
initiating of contact between a tip and the localised site; and/or
depositing one or more carbon-containing particles at the localised site.

The tip may be a scanning probe microscope (SPM) tip. In addition, the tip may be made from carbon or a carbon-containing material, and/or may include carbon or a carbon-containing material located at a contact end of the tip. Furthermore, the tip may be used to transfer one or more carbon-containing particles to the localised site.

The tip may be kept at a lower temperature than the surface of the substrate so as to initiate cooling of the localised site upon contact between the tip and the localised site. This in turn may be used to modify the substrate cooling rate at the localised site.

The deposition of one or more carbon-containing particles at the localised site may involve the deposition of, for example, graphene and benzene. It is envisaged that other material that aids graphene nucleation may be deposited at the localised site in place of the one or more carbon-containing particles.

Preferred embodiments of the invention will now be described, by way of non-limiting examples, with reference to the accompanying drawings in which:

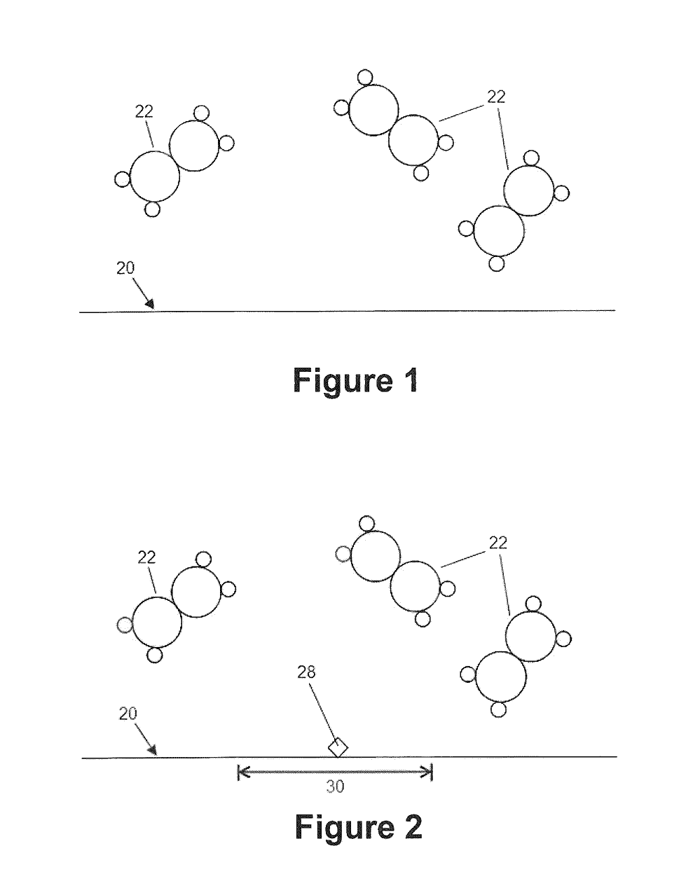

FIG. 1 shows a substrate with a surface that is exposed to ethylene gas;

FIG. 2 illustrates the deposition of a catalyst on the surface of FIG. 1 to increase the rate of decomposition of absorbed ethylene molecules;

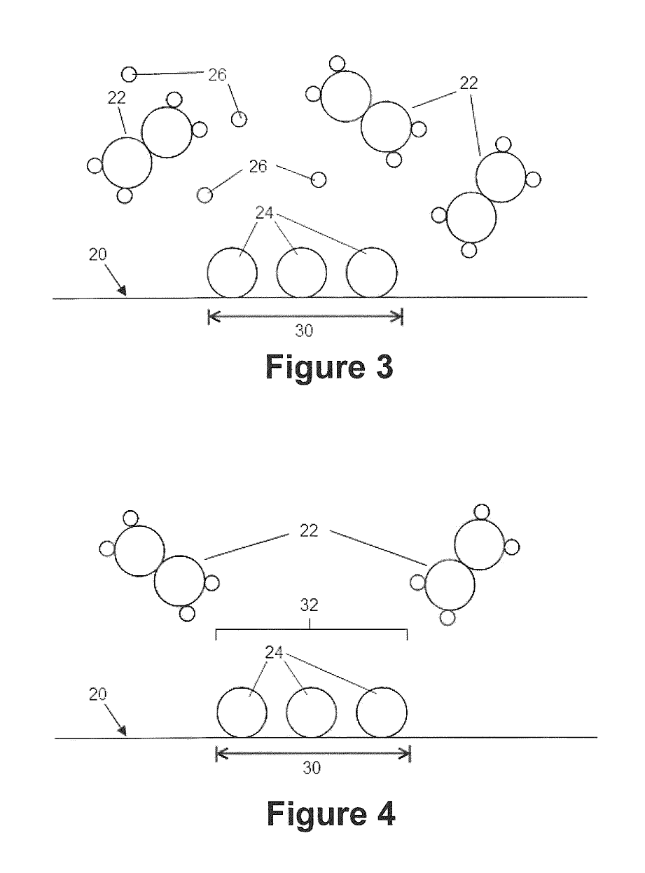

FIG. 3 illustrates the decomposition of absorbed ethylene molecules to form a graphene nucleus on the surface of FIG. 1;

FIG. 4 shows a stable graphene nucleus that is formed on the surface of FIG. 1;

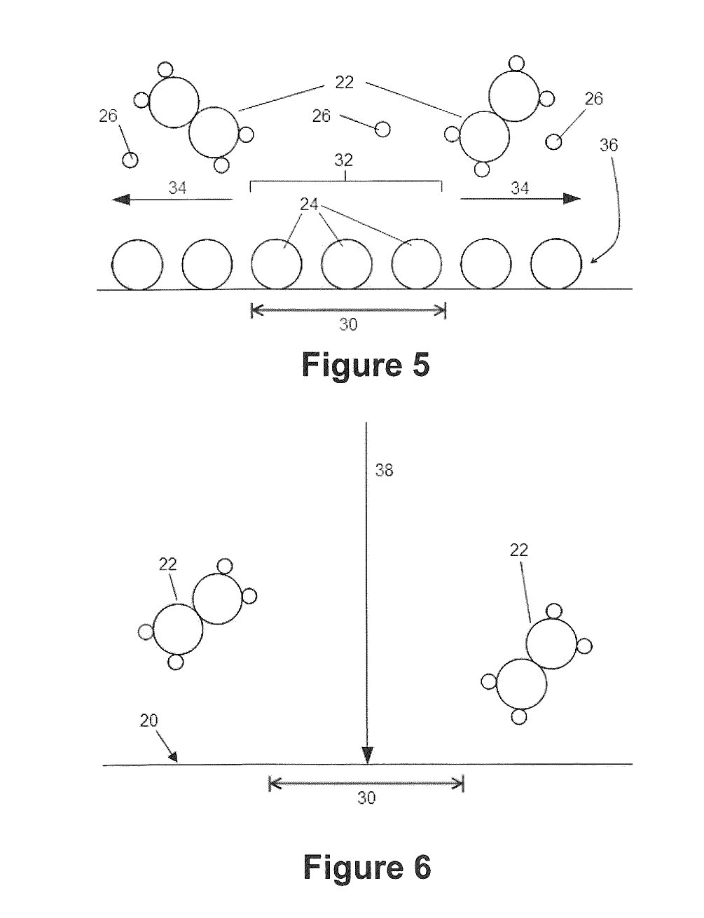

FIG. 5 illustrates the growth of graphene from the stable graphene nucleus of FIG. 4;

FIG. 6 shows the use of a focused laser beam to impinge a localised site on a surface of a substrate;

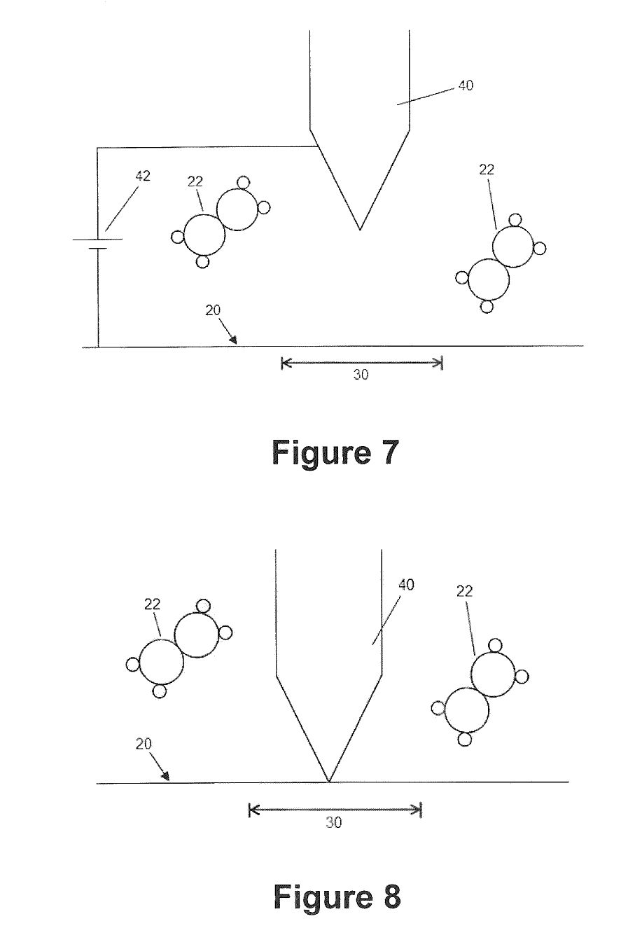

FIG. 7 shows the application of a voltage difference between a localised site on a surface of a substrate and a scanning probe microscope tip held in close proximity to the localised site; and

FIG. 8 shows the use of a scanning probe microscope tip to contact a localised site on a surface of a substrate.

A method according to a first embodiment of the invention is described with reference to FIGS. 1 to 5.

Firstly, a substrate is selected. The substrate defines a flat surface 20 for formation of a graphene film, and is made from rhodium, Rh(111).

In other embodiments, it is envisaged that the substrate may be made from or may include:
nickel or copper, each of which has a similar lattice structure to graphene; or
copper, iridium or platinum, each of which has a relatively weak interaction with carbon and a low solubility of carbon. These characteristics not only aid the subsequent transfer of the resultant graphene film to a different substrate, but also make it easier to control the carbon adatom density on the surface.

The surface 20 is cleaned using conventional surface cleaning techniques, e.g. ion erosion or chemical washing, in order to ensure that it is free of existing graphene nuclei.

The substrate is then exposed to ethylene gas, as shown in FIG. 1, which results in the absorption of ethylene molecules 22 on the surface 20 of the substrate. This is followed by the decomposition of the absorbed ethylene molecules 22 to form carbon atoms 24 and volatile components 26. The carbon atoms 24 either remain on the surface 20 or dissolve into the substrate, while the volatile components 26 are pumped away using a vacuum pumping system.

It is envisaged that, in other embodiments, the ethylene gas may be replaced by another carbon-containing precursor gas or another type of carbon source.

For a substrate made from Rh(111), it was found that graphene nucleation is enabled by controlling the gas pressure of the ethylene gas to be at least 3×10⁻⁶ mbar and graphene growth is enabled by controlling the gas pressure of the ethylene gas to be at least 1×10⁻⁹ mbar, when the temperature at the surface is at 975 K.

Controlling the gas pressure of the ethylene gas to be less than 3×10⁻⁶ mbar therefore sets the rate of decomposition of the absorbed ethylene molecules 22 at the surface 20 to control the density of carbon adatoms 24 on the surface 20 of the substrate to be lower than the required density of carbon adatoms 24 for graphene nucleation to take place at an observable rate. This prevents formation of a stable graphene nucleus that exceeds a critical nucleus size, and thereby prevents graphene nucleation from taking place on the surface 20 of the substrate.

Similarly, controlling the gas pressure of the ethylene gas to be at least 1×10⁻⁹ mbar sets the rate of decomposition of the absorbed ethylene molecules 22 at the surface 20 to control the density of carbon adatoms 24 on the surface 20 of the substrate to be higher than the required density of carbon adatoms 24 for graphene growth to take place at an observable rate. This enables graphene growth whilst preventing graphene nucleation from taking place, because the required density of carbon adatoms 24 for graphene growth to occur at an observable rate is lower than the required density of carbon adatoms 24 for graphene nucleation to occur at an observable rate.

It will be appreciated that the required densities of carbon adatoms 24 for graphene nucleation and graphene growth to take place at an observable rate and the critical nucleus size for formation of a stable graphene nucleus varies with the type and temperature of substrate used.

Thus, the gas pressure of the ethylene gas is controlled to be at least 1×10⁻⁹ mbar but less than 3×10⁻⁶ mbar at a surface temperature of 975 K to simultaneously inhibit graphene nucleation and enable graphene growth on the surface of the substrate.

It will be appreciated that the gas pressure of the ethylene gas required to inhibit graphene nucleation and enable graphene growth on the surface 20 of the substrate varies with the type of substrate used and temperature of the surface 20.

Control of the gas pressure of the ethylene gas at the surface 20 of the substrate in this manner therefore simultaneously inhibits graphene nucleation and enables graphene growth on the surface 20. However, the lack of an existing, stable graphene nucleus on the surface 20 prevents graphene growth from taking place.

A catalyst 28 is then deposited at a localised site 30 on the surface, as shown in FIG. 2. Examples of suitable catalysts include nickel, rhodium, ruthenium, iridium, cobalt and iron.

Deposition of the catalyst 28 increases the rate of decomposition of the absorbed ethylene molecules 22, and thereby increases the density of carbon adatoms 24, at the localised site 30 so as to permit formation of a stable graphene nucleus 32, as shown in FIG. 3. Meanwhile the rate of decomposition of the absorbed ethylene molecules 22 on the surface 20 of the substrate and away from the localised site 30 remains unchanged and thereby prevents graphene nucleation from taking place elsewhere on the surface 20, away from the localised site 30.

The newly formed, stable graphene nucleus at the localised site then covers the catalyst, which is thereby prevented from further participating in the decomposition of the absorbed ethylene molecules 22. This in turn causes the rate of decomposition of the absorbed ethylene molecules 22 at the localised site 30 to revert to its previous rate of decomposition, which thereby prevents further graphene nucleation from taking place at the localised site 30, as shown in FIG. 4.

The newly formed graphene nucleus 32 provides a seed, to which carbon atoms 24 formed from ongoing decomposition of the absorbed ethylene molecules 22 attach. This in turn results in growth 34 and increase in size of the graphene nucleus 32, which readily occurs due to the gas pressure of the ethylene gas at the surface 20 already being controlled to enable graphene growth 34 on the surface. Absence of the catalyst does not affect graphene growth 34 because, as outlined earlier, the gas pressure of the ethylene gas is sufficient to produce the required density of carbon adatoms 24 on the surface 20 to enable graphene growth 34 to take place.

In the event that the newly formed, stable graphene nucleus does not completely cover the catalyst, the catalyst may adhere to the edges of the growing graphene domain. This causes the edges of the growing graphene domain to be more reactive and thereby increase the growth rate of the graphene domain.

The graphene nucleus 24 continues to grow and eventually forms a graphene film 36 that covers the entire surface 20 of the substrate. The amount of available ethylene gas for graphene growth 34 may be controlled to limit the final size of the graphene film 36.

Since there are no other stable graphene nuclei on the surface 20 to provide seeds for subsequent graphene growth 34, the resultant graphene film 36 is a single-domain film without any domain boundaries.

The control of the gas pressure of the ethylene gas at the surface 20 of the substrate to simultaneously inhibit graphene nucleation and enable graphene growth on the surface 20, and the deposition of the catalyst 28 to initiate temporary graphene nucleation at the localised site 30, therefore enable formation of a single-domain graphene film 36 without domain boundaries on the surface 20.

Such control of the gas pressure of the ethylene gas at the surface 20 of the substrate is advantageous in that it prevents random formation of stable graphene nuclei 32 on the surface 20, which increases the risk of formation of multiple graphene domains and thereby a multi-domain graphene film.

It is envisaged that, in other embodiments of the invention, the gas pressure of the ethylene gas may be initially controlled to be less than 1×10⁻⁶ mbar to inhibit both graphene nucleation and graphene growth on the surface 20 prior to the deposition of the catalyst 28 at the localised site 30. After the stable graphene nucleus 32 is formed at the localised site, the gas pressure of the ethylene gas may then be controlled to be at least 1×10⁻⁹ mbar but less than 3×10⁻⁶ mbar to simultaneously inhibit graphene nucleation and enable graphene growth so as to allow the graphene film 36 to be grown from the stable graphene nucleus 32 whilst preventing further graphene nucleation.

Application of a temporary change of one or more of the ambient conditions at a localised site on the surface of the substrate to initiate graphene nucleation may be carried out using a number of other ways.

Methods according to the second, third and fourth embodiments of the invention are shown in FIGS. 6 to 8 respectively. The second, third and fourth methods are similar to the first method and like features share the same reference numerals.

The second, third and fourth methods differ from the first method in that that, instead of depositing a catalyst at the localised site to increase the rate of decomposition of absorbed ethylene molecules, each method involves a different way of applying a temporary change in one or more of the ambient conditions at the localised site to initiate temporary graphene nucleation.

The second method in FIG. 6 involves the use of a focused laser beam 38 to temporarily impinge the localised site 30 on the surface 20 of the substrate.

The use of the focused laser beam locally increases the temperature at the localised site to increase the rate of decomposition of the absorbed ethylene molecules 22 so as to initiate temporary graphene nucleation at the localised site 30.

In other embodiments, it is envisaged that a focused ion beam or electron beam may be used to temporarily impinge the localised site 30 to induce and thereby enhance decomposition of the absorbed ethylene molecules 22 at the localised site. This increases the rate of decomposition of the absorbed ethylene molecules 22 so as to initiate temporary graphene nucleation at the localised site 30.

The third method in FIG. 7 involves the use of a scanning probe microscope (SPM) tip 40. The SPM tip 40 is brought into close proximity with the localised site 30 on the surface 20 of the substrate. A voltage difference 42 is then temporarily applied between the surface 20 of the substrate and the SPM tip 40. Application of the voltage difference 42 between the surface 20 and the localised site 30 leads to introduction of additional energy into the localised site 30, which may be controlled to locally increase the temperature at the localised site 30 or ionise the absorbed ethylene molecules 22 at the localised site 30, both of which enhances the decomposition of the absorbed ethylene molecules 22. This thereby increases the rate of decomposition of the absorbed ethylene molecules 22 so as to initiate temporary graphene nucleation at the localised site 30.

The fourth method in FIG. 8 involves the use of a SPM tip 40, which is temporarily brought into contact with the surface 20 of the substrate at the localised site 30. Contact between the SPM tip 40 and the surface at the localised site 30 introduces a local defect, which creates a low energy site at the localised site 30. The low energy site reduces the energy threshold required to initiate temporary graphene nucleation at the localised site 30.

A method according to a fifth embodiment of the invention involves the formation of a graphene film through segregation of absorbed carbon atoms.

A Rh(111) substrate, with a thickness of 1 mm, is selected and is cleaned using conventional surface cleaning techniques, e.g. ion erosion or chemical washing, in order to ensure that it is free of existing graphene nuclei.

The substrate is then exposed to ethylene gas at a pressure of 1×10⁻⁸ mbar for 10 minutes to introduce carbon atoms into the substrate at a first temperature of 1000 K. The ethylene gas pressure is then reduced to zero bar before the substrate is cooled to a second, lower temperature in the range of 700 K to 950 K so as to lower the solubility of carbon in the substrate. This causes absorbed carbon atoms to segregate on the surface and thereby contribute to the carbon adatom density on the surface.

Reducing the ethylene gas pressure to zero bar prior to cooling the substrate to the second, lower temperature makes it easier to control the carbon adatom density on the surface.

The difference in carbon solubility of the substrate at the first and second temperatures, and the ratio of carbon adatom density on the surface to carbon concentration of the bulk substrate, affects the carbon adatom density on the surface. Thus, the substrate temperature and the carbon concentration of the substrate, together with the gas pressure of the ethylene gas and the rate of decomposition of absorbed ethylene molecules at both temperatures, define ambient conditions that are controlled to simultaneously inhibit graphene nucleation and enable graphene growth on the surface.

The ethylene gas pressure is then increased to 1×10⁻⁸ mbar, which is sufficiently high to enable graphene growth to occur but low enough to inhibit graphene nucleation. A catalyst is then deposited at the localised site to increase the rate of decomposition of absorbed ethylene molecules and thereby increase the carbon adatom density at the localised site, so as to permit formation of a stable graphene nucleus. Meanwhile the ambient conditions elsewhere on the surface of the substrate and away from the localised site remain unchanged and thereby prevent graphene nucleation from taking place elsewhere on the surface, away from the localised site.

The newly formed, stable graphene nucleus then covers the catalyst and thereby prevents the catalyst from further participating in the decomposition of the absorbed ethylene molecules. This in turn causes the rate of decomposition of absorbed ethylene molecules at the localised site to revert to its previous rate of decomposition, which thereby prevents further graphene nucleation from taking place at the localised site.

The newly formed graphene nucleus provides a seed, to which carbon atoms formed from ongoing segregation of the absorbed carbon atoms attach. The graphene nucleus continues to grow through a combination of decomposition of the absorbed ethylene molecules and segregation of absorbed carbon atoms on the surface, and eventually forms a graphene film that covers the entire surface of the substrate.

Optionally, after formation of the stable graphene nucleus, the ethylene gas pressure may be reduced to zero bar, so that graphene growth only occurs through segregation of the carbon atoms.

In other embodiments, it is envisaged that the Rh(111) substrate may be replaced by a Cu(111) substrate with a thickness of 0.5 mm, while the first and second temperatures may be set at 1300 K and 1100 K respectively, and the ethylene gas pressure may be set at 1×10⁴ mbar.

A method according to a sixth embodiment of the invention involves the formation of a graphene film through control of carbon atom density on the surface of the substrate.

A Ir(111) substrate is selected and is cleaned using conventional surface cleaning techniques, e.g. ion erosion or chemical washing, in order to ensure that it is free of existing graphene nuclei.

The substrate is then exposed to ethylene gas at a pressure of 1×10⁻⁸ mbar for 10 minutes to supply carbon atoms to the surface of the substrate at a first temperature of 1000 K, before the ethylene gas pressure is reduced to zero bar.

A carbon-containing particle, e.g. graphene or benzene, is then deposited at the localised site by using a SPM tip to transfer the carbon-containing particle to the localised site, whereby the carbon-containing particle is located at a contact end of the SPM tip.

Alternatively deposition of the carbon-containing particle may be carried out by bringing a tip into contact with the surface at the localised site, whereby the tip is made from carbon or a carbon-containing material.

Deposition of the carbon-containing particle directly increases the carbon adatom density at the localised site so as to cause formation of a stable graphene nucleus. Meanwhile the carbon adatom density elsewhere on the surface of the substrate and away from the localised site remains unchanged and thereby prevents graphene nucleation from taking place elsewhere on the surface, away from the localised site.

The newly formed graphene nucleus provides a seed, to which carbon adatoms on the surface and carbon atoms from within the substrate attach. The graphene nucleus continues to grow and eventually forms a graphene film that covers the entire surface of the substrate.

Optionally, after formation of the stable graphene nucleus, the growth of the graphene film may be enhanced by increasing the ethylene gas pressure to 1×10⁻⁸ mbar, which is sufficiently high to enable graphene growth to occur but low enough to inhibit new graphene nucleation.

In further embodiments of the invention, it is envisaged that a temporary change of one or more ambient conditions may be applied at a plurality of localised sites on the surface of the substrate to create a stable graphene nuclei at each localised site. It is also envisaged that, in still further embodiments of the invention, the position of the localised sites may be controlled so as to create a specific distance between neighbouring graphene nuclei.

In still further embodiments, it is envisaged that a graphene film may be manufactured in accordance with a combination of two or more of the above-described methods of forming a graphene film on a surface of a substrate.

In each of the embodiments shown above, the carbon source is a carbon-containing gas, carbon atoms dissolved in the substrate or carbon atoms on the surface. It is envisaged that, in other embodiments, the carbon source may be replaced by or may further include one or more of: a carbon-containing gas, a carbon-containing liquid, carbon contamination of the substrate, carbon atoms on the surface, carbon-containing molecules on the surface, carbon atoms dissolved in the substrate, carbon-containing molecules dissolved in the substrate, an atomic carbon source and carbon ions.

1. A method of forming a graphene film on a surface of a substrate comprising the steps of:
(i) locating a carbon source at, or in a vicinity of, the surface of the substrate;
(ii) controlling ambient conditions at the surface of the substrate to inhibit graphene nucleation on the surface;
(iii) applying a temporary change of one or more of the ambient conditions at a localised site on the surface of the substrate to initiate graphene nucleation at the localised site;
(iv) controlling the ambient conditions at the surface of the substrate, following initiation of graphene nucleation at the localised site, to simultaneously inhibit graphene nucleation and enable graphene growth on the surface.

2. A method according to claim 1, wherein the carbon source includes one or more of: a carbon-containing gas, a carbon-containing liquid, carbon contamination of the substrate, carbon atoms on the surface, carbon-containing molecules on the surface, carbon atoms dissolved in the substrate, carbon-containing molecules dissolved in the substrate, an atomic carbon source and carbon ions.

3. A method according to claim 1 wherein the step of controlling ambient conditions at the surface of the substrate to inhibit graphene nucleation on the surface further involves simultaneously controlling the ambient conditions at the surface of the substrate to enable graphene growth on the surface.

4. A method of forming a graphene film according to claim 1 wherein the ambient conditions are selected from a group including temperature, gas pressure, rate of decomposition of absorbed carbon-containing molecules, carbon adatom density on the surface of the substrate, carbon concentration of the substrate, electrical potential, substrate cooling rate and surface chemistry.

5. A method according to claim 4 wherein the step of controlling ambient conditions at the surface of the substrate involves controlling the temperature at the surface to be in the range of 500 K to 2000 K.

6. A method according to claim 5 wherein the step of applying a temporary change of one or more of the ambient conditions at a localised site on the surface of the substrate involves temporarily changing the temperature at the localised site to be in the range of 1 K to 2000 K.

7. A method according to claim 4 wherein the step of controlling ambient conditions at the surface of the substrate involves controlling the gas pressure at the surface to be in the range of 1×10⁻⁹ mbar to 3 bar.

8. A method according to claim 7 wherein the step of applying a temporary change of one or more of the ambient conditions at a localised site on the surface of the substrate involves temporarily changing the gas pressure at the localised site to be in the range of 1×10⁻⁸ mbar to 10 bar.

9. A method according to claim 4 wherein the step of controlling ambient conditions at the surface of the substrate involves controlling the rate of decomposition of absorbed carbon-containing molecules at the surface to be in the range of 0.0001% to 10%.

10. A method according to claim 9 wherein the step of applying a temporary change of one or more of the ambient conditions at a localised site on the surface of the substrate involves temporarily changing the rate of decomposition of absorbed carbon-containing molecules at the localised site to be in the range of 0.01% to 100%.

11. A method according to claim 4 wherein the step of controlling ambient conditions at the surface of the substrate involves controlling the carbon concentration of the substrate at the surface to be in the range of 0.0001% to 10%.

12. A method according to claim 11 wherein the step of applying a temporary change of one or more of the ambient conditions at a localised site on the surface of the substrate involves temporarily changing the carbon concentration of the substrate at the localised site to be in the range of 0.01% to 100%.

13. A method according to claim 4 wherein the step of controlling ambient conditions at the surface of the substrate involves controlling the electrical potential at the surface to be in the range of 0 to 1 kV.

14. A method according to claim 13 wherein the step of applying a temporary change of one or more of the ambient conditions at a localised site on the surface of the substrate involves temporarily changing the electrical potential at the localised site to be in the range of 0.1 V to 10 kV.

15. A method according to claim 4 wherein the step of controlling ambient conditions at the surface of the substrate involves controlling the substrate cooling rate at the surface to be in the range of 0.01 K/sec to 1000 K/sec.

16. A method according to claim 15 wherein the step of applying a temporary change of one or more of the ambient conditions at a localised site on the surface of the substrate involves temporarily changing the substrate cooling rate at the localised site to be in the range of 0.1 K/sec to 1500 K/sec.

17. A method of forming a graphene film according to claim 1 wherein the step of applying a temporary change of one or more of the ambient conditions at a localised site on the surface of the substrate involves formation of a single graphene nucleus on the surface.

18. A method of forming a graphene film according to claim 1 further including the step of removing the temporary change of one or more of the ambient conditions at the localised site subsequent to the step of applying a temporary change of one or more of the ambient conditions at a localised site on the surface of the substrate.

19. A method of forming a graphene film according to claim 1 wherein the step of applying a temporary change of one or more of the ambient conditions at a localised site on the surface of the substrate involves:
impingement of a focused laser beam, focused ion beam or electron beam at the localised site;
depositing a catalyst at the localised site to increase a rate of decomposition of absorbed carbon-containing molecules at the localised site;
positioning of a tip near the localised site and applying a voltage difference between the localised site and the tip;
initiating contact between a tip and the localised site; and/or
depositing one or more carbon-containing particles at the localised site.
